(19) United States
(12) Patent Application Publication
(10) Pub. No.: US 2017/0243752 A1
(43) Pub. Date: Aug. 24, 2017

(54) POLISHING COMPOSITION AND METHOD FOR PRODUCING POLISHING COMPOSITION

(71) Applicant: FUJIMI INCORPORATED, Kiyosu-shi, Aichi (JP)

(72) Inventor: Akihito YASUI, Kiyosu-shi, Aichi (JP)

(73) Assignee: FUJIMI INCORPORATED, Kiyosu-shi, Aichi (JP)

(21) Appl. No.: 15/503,463

(22) PCT Filed: Jul. 30, 2015
(86) PCT No.: PCT/JP2015/071714

§ 371 Date: Feb. 13, 2017

(30) Foreign Application Priority Data
Aug. 29, 2014 (JP) 2014-176271

(51) Int. Cl. H01L 21/3105; C09G 1/02; B24B 37/04

(52) U.S. Cl. CPC H01L 21/31053; B24B 37/044; H01L 21/31058; C09G 1/02

(57) ABSTRACT

Provided is a polishing composition which is capable of sufficiently suppressing a polishing speed for a low relative permittivity material.

Disclosed is a polishing composition to be used for polishing a material having a relative permittivity of 4 or less, the polishing composition including abrasive grains and an organic compound, the organic compound having a polyoxyalkylene group and an aliphatic hydrocarbon group containing three or more carbon atoms.

### TECHNICAL FIELD

The present invention relates to a polishing composition and a method for producing a polishing composition.

### BACKGROUND ART

In regard to the development of semiconductor devices represented by semiconductor integrated circuit (hereinafter, described as LSI), there has been a demand in recent years for high density and high integration brought by micronization of wiring and high-degree lamination, for the purpose of device size reduction and high speed processing. In such advanced devices, since a distance between wires is very short, when an insulating film having a high dielectric constant is used, electrical defects may occur between wires. Therefore, for the purpose of increasing a processing speed of LSI, it is required to use in an interlayer insulating film a material having a low capacity between wires and low relative permittivity (hereinafter, also referred to as Low-k material).

SiO₂, which is a conventional material for an interlayer insulating film for semiconductor devices, has a relative permittivity of about 3.8 to 4.2. However, as a wire width becomes narrower, a relative permittivity of an interlayer insulating film material should also be decreased. For example, a device having a wire width of 130 nm requires a material having a relative permittivity of about 2.5 to 3.0.

For a material having low relative permittivity that is used as an interlayer insulating film, for example, organic-inorganic hybrid-based materials such as SiOC-based materials (for example, SiOC containing multiple Si—C bonds or Si—H bonds) and methylsilsesquioxane have been known.

For a polishing technology for such a Low-k material, a technology of polishing a film having low relative permittivity using a polishing composition including silica, a benzotriazole compound and an amino alcohol (JP 2008-091569 A) has been proposed.

### SUMMARY OF INVENTION

In regard to a low relative permittivity material that is used as an interlayer insulating film, it is required to suppress a polishing speed in order to avoid any loss. However, since a low relative permittivity material has very low strength, the polishing composition disclosed in JP 2008-091569 A cannot suppress a polishing speed for a low relative permittivity material. Thus, there has been a demand for further improvements.

It, therefore, is an object of the present invention to provide a polishing composition that is capable of sufficiently suppressing a polishing speed for a low relative permittivity material, and a method for producing the polishing composition.

In order to solve the problems described above, the present inventors repeatedly conducted thorough investigations. As a result, they have found that the problems can be solved by using a polishing composition which includes abrasive grains and an organic compound having a particular structure. Then, the present inventors finally completed the present invention based on the findings.

That is, the present invention is a polishing composition used for polishing a material having a relative permittivity of 4 or less, the polishing composition including abrasive grains and an organic compound, wherein the organic compound has a polyoxyalkylene group and an aliphatic hydrocarbon group containing three or more carbon atoms.

### DESCRIPTION OF EMBODIMENTS

According to one embodiment of the present invention, there is provided a polishing composition including abrasive grains and an organic compound, in which the organic compound is a compound having a polyoxyalkylene group and an aliphatic hydrocarbon group containing three or more carbon atoms, and the polishing composition is used for polishing a material having a relative permittivity of 4 or less. By such a configuration, a polishing speed for a low relative permittivity material can be sufficiently suppressed.

Furthermore, according to another embodiment of the present invention, according to another embodiment of the present invention, there is provided a method for producing a polishing composition, the method including a step of mixing abrasive grains with an organic compound, in which the organic compound has a polyoxyalkylene group and an aliphatic hydrocarbon group containing three or more carbon atoms, and the polishing composition is used for polishing a material having a relative permittivity of 4 or less. By such a configuration, a polishing composition that can sufficiently suppress a polishing speed for a low relative permittivity material can be provided.

Although detailed reasons why effects as described above can be attained by the polishing composition according to embodiments of the present invention are not clearly understood, it is speculated that the following reasons apply.

The organic compound included in the polishing composition according to one embodiment of the present invention has a polyoxyalkylene group and an aliphatic hydrocarbon group containing three or more carbon atoms. By forming a hydrogen bond between non-covalent electron pairs on an oxygen atom of the polyoxyalkylene group present in the organic compound and an outermost surface of a low relative permittivity material film, the organic compound adheres to the material film as a protective film. Since the aliphatic hydrocarbon group moiety does not attract to an object to be polished, a steric barrier is produced. As a result, it is speculated that such a barrier absorbs collision of abrasive grains to a low relative permittivity material film, to suppress a polishing speed for the low relative permittivity material. Meanwhile, the mechanism described above is based on speculations, and the present invention is not intended to be limited by the above-described mechanism.

### [Object to be Polished]

An object to be polished according to one embodiment of the present invention is a material having a relative permittivity of 4 or less. As long as the object to be polished according to the present invention includes a material having a relative permittivity of 4 or less, the object to be polished may further have a metal layer such as a barrier layer, a metal wiring layer, and the like.

Here, the upper limit of the relative permittivity of the object to be polished according to one embodiment of the present invention is 4, and the upper limit is preferably 3.5, and more preferably 3.0. On the other hand, the lower limit of the relative permittivity is not particularly limited; however, the lower limit is preferably 1.1, more preferably 1.5, and even more preferably 1.7. When the relative permittivity is in the range as described above, a film has more satisfactory mechanical strength and more satisfactory film adhesiveness, and an interlayer insulating film can be effectively prevented from being electrically charged. If the relative permittivity exceeds 4, a distance between wires is shortened along with micronization, and consequently, an interlayer insulating film existing between the wires can be easily charged as in the case of a condenser. Thus, reliability of signals tends to be lowered. On the other hand, when the relative permittivity is adjusted to be 1.1 or higher, film can be strengthened, and also, frequency of problems occurring in the adhesiveness of film can be further decreased.

Specific examples of the material having a relative permittivity of 4 or less include a silicon oxycarbide (SiOC), a fluorine-containing silicon oxide (SiOF), and an organic polymer. More specifically, examples of SiOC-based materials include HSG-R7 (manufactured by Hitachi Chemical Co., Ltd.) and BLACKDIAMOND (registered trademark) (Applied Materials, Inc.). The object to be polished according to the present invention may further include SiO₂ in addition to these materials.

The object to be polished according to one embodiment of the present invention may include a metal layer such as a barrier layer. The material included in the metal layer is not particularly limited, and examples thereof include tungsten, copper, aluminum, hafnium, cobalt, nickel, titanium, tantalum, titanium, gold, silver, platinum, palladium, rhodium, ruthenium, iridium, and osmium. These metals may be incorporated into the metal layer in the form of an alloy or a metal compound. Preferred examples include tungsten, copper, ruthenium, and tantalum. These metals may be used singly or in combination of two or more kinds thereof.

Furthermore, the metal that is incorporated into the metal wiring layer is also not particularly limited, and examples thereof include copper, aluminum, hafnium, cobalt, nickel, titanium, and tungsten. These metals may be incorporated into the metal wiring layer in the form of an alloy or a metal compound. Preferred examples include copper and a copper alloy. These metals may be used singly, or in combination of two or more kinds thereof.

Next, the polishing composition according to one embodiment of the present invention will be explained in detail.

### [Organic Compound]

The organic compound according to one embodiment of the present invention has a polyoxyalkylene group and an aliphatic hydrocarbon group containing three or more carbon atoms. The organic compound having such a structure can attain an effect of suppressing a polishing speed for a low relative permittivity material. The organic compound may be used singly, or two or more kinds thereof may be used in combination.

Examples of the polyoxyalkylene group include, for example, a polyoxyethylene group, a polyoxypropylene group, a polyoxybutylene group, a block polyoxyalkylene group of a polyoxyethylene group and a polyoxypropylene group, a random polyoxyalkylene group of a polyoxyethylene group and a polyoxypropylene group, a block polyoxyalkylene group of a polyoxyethylene group and a polyoxybutylene group, and a random polyoxyalkylene group of a polyoxyethylene group and a polyoxybutylene group.

An average number of added moles of the polyoxyalkylene group existing in the organic compound is preferably 2 or larger, more preferably 5 or larger, and even more preferably 10 or larger, from the viewpoint of easy adhesion of the organic compound to a law relative permittivity material. Furthermore, from the viewpoint of preventing a polishing speed for a low relative permittivity material from being excessively suppressed, the average number of added moles is preferably 180 or less, more preferably 170 or less, and even more preferably 160 or less. The average number of added moles is an average value of the mole number of oxyalkylene groups to be added per mole of the organic compound.

In the organic compound, a proportion of oxyethylene groups relative to an average number of added moles of polyoxyalkylene groups is preferably 50 mol % to 100 mol %, more preferably 80 mol % to 100 mol %, and even more preferably 100 mol %, from the viewpoint of easy formation of hydrogen bonding with a low relative permittivity material, and effective suppression of a polishing speed for a low relative permittivity material. That is, the polyoxyalkylene group is more preferably a polyoxyethylene group. A polyoxyethylene group is preferable because the organic compound can more easily adsorb to an outermost surface of a low relative permittivity material via hydrogen bonding.

The organic compound is particularly preferably an organic compound having as a polyoxyalkylene group a polyoxyethylene group with an average number of added moles of 10 or larger. The average number of added moles of 10 or larger is more preferable in terms that the organic compound can more easily adhere to a low relative permittivity material to improve effect of suppressing a polishing speed.

When the polyoxyalkylene group of the organic compound includes two or more kinds of oxyalkylene groups, the form of addition of the oxyalkylene group units may be a block-like form or may be a random-like form, as described above. A block-like form is preferred.

The aliphatic hydrocarbon group containing three or more carbon atoms existing in the organic compound is not particularly limited, and the aliphatic hydrocarbon group may be saturated or unsaturated, may be chain-like or cyclic, and may further have a substituent. When the aliphatic hydrocarbon group is a cyclic group, the group may be a monocyclic group or a polycyclic group. The aliphatic hydrocarbon group containing three or more carbon atoms is preferably a saturated or unsaturated chain-like aliphatic hydrocarbon group.

Examples of the chain-like aliphatic hydrocarbon group include a linear or branched alkyl group having 3 to 30 carbon atoms, such as a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, an eicosanyl group, a heneicosanyl group, a docosanyl group, a triacontanyl group, an isopropyl group, an isobutyl group, a sec-butyl group, a t-butyl group, a 1-ethylpentyl group, a 2-ethylhexyl group, an isoheptyldecyl group, a 1-hexylheptyl group, and an isostearyl group; a linear or branched alkenyl group having 3 to 30 carbon atoms, such as a propenyl group, a butenyl group, a pentenyl group, a hexenyl group, a heptenyl group, an octenyl group, a nonenyl group, a decenyl group, an undecenyl group, a dodecenyl group, a tridecenyl group, a tetradecenyl group, a pentadecenyl group, a hexadecenyl group, a heptadecenyl group, an octadecenyl group, an octadecatrienyl group, a (5Z, 8Z, 11Z, 14Z)-nonadeca-5,8,11,14-tetraenyl group, an eicosenyl group, a heneicosenyl group, a docosenyl group, and a triacontenyl group; and a linear or branched alkynyl group having 3 to 30 carbon atoms, such as a propynyl group, a butynyl group, a pentynyl group, a hexynyl group, a heptynyl group, an octynyl group, a nonynyl group, a decynyl group, a dodecynyl group, a tetradecynyl group, a hexadecynyl group, and an eicosynyl group. Among these, a linear or branched alkyl group or alkenyl group having 3 to 30 carbon atoms is preferred, and more preferred examples include an undecyl group, a dodecyl group, a pentadecyl group, a heptadecyl group, an isostearyl group, an undecenyl group, and a heptadecenyl group.

The cyclic aliphatic hydrocarbon group is preferably a cycloalkyl group having 3 to 30 carbon atoms, and examples thereof include monocyclic aliphatic hydrocarbon groups such as a cyclopropyl group, a cyclobutyl group, a cyclopentyl group, a cyclohexyl group, a cycloheptyl group, and a cyclooctyl group; and polycyclic aliphatic hydrocarbon groups such as an adamantyl group, a norbornyl group, a bornyl group, a camphenyl group, a decahydronaphthyl group, a tricyclodecanyl group, a tetracyclodecanyl group, a camphoroyl group, a dicyclohexyl group, and a pinenyl group.

The aliphatic hydrocarbon group containing three or more carbon atoms may be bonded to the polyoxyalkylene group through another substituent, or may be directly bonded thereto.

When the aliphatic hydrocarbon group containing three or more carbon atoms is directly bonded to the polyoxyalkylene group, the aliphatic hydrocarbon group containing three or more carbon atoms may be bonded to an oxygen atom at the terminal of the polyoxyalkylene group, or may be bonded to a carbon atom of an alkylene group in the polyoxyalkylene group unit. However, the aliphatic hydrocarbon group is preferably bonded to an oxygen atom at the terminal of the polyoxyalkylene group.

Examples of such an organic compound include a polyoxyalkylene alkyl ether such as a polyoxyethylene alkyl ether. A more specific example may be POE(5)-5-hexylheptyl ether.

When the polyoxyalkylene group is bonded to the aliphatic hydrocarbon group containing three or more carbon atoms through another substituent, the another substituent is not particularly limited. Examples thereof include —COO—, —OCO—, —CO—, —N—, —S—, —SO—, —SO₂—, and —NRCO— (wherein R represents a hydrogen atom or an alkyl group having 1 to 20 carbon atoms).

Examples of such an organic compound include a polyoxyalkylene-fatty acid ester and a polyoxyalkylene-alkylamine.

Among these, a preferred example is a polyoxyalkylene-fatty acid ester having a polyoxyalkylene group and an aliphatic hydrocarbon group containing three or more carbon atoms bonded through an ester bond. Examples of the fatty acid ester group include fatty acid ester groups derived from a saturated fatty acid, an unsaturated fatty acid, and a branched fatty acid.

Examples of the fatty acid ester group include ester groups derived from caprylic acid, nonanoic acid, decanoic acid, lauric acid, tridecanoic acid, isotridecanoic acid, myristic acid, pentadecanoic acid, palmitic acid, heptadecanoic acid, stearic acid, nonadecanoic acid, behenic acid, dodecenic acid, tetradecenic acid, hexadecenic acid, palmitoleic acid, oleic acid, vaccenic acid, linoleic acid, linolenic acid, arachidonic acid, and isostearic acid. Among them, fatty acid ester groups derived from lauric acid, palmitic acid, isostearic acid and oleic acid are preferred. Regarding the organic compound described above, the above-mentioned fatty acid ester groups may be used singly, or two or more kinds thereof may be used together.

The organic compound explained above is not particularly limited. Examples thereof include a polyoxyalkylene-fatty acid ester, a polyoxyalkylene-sorbitan fatty acid ester, and a polyoxyalkylene-glycerin fatty acid ester.

From the viewpoint of easy availability, the organic compound is preferably a sorbitan derivative, which includes the aforementioned polyoxyalkylene-sorbitan fatty acid ester or the like. Among these, a polyoxyalkylene-sorbitan fatty acid ester is more preferred, and a polyoxyethylene (POE)-sorbitan fatty acid ester is even more preferred.

Specific examples of the polyoxyethylene (POE)-sorbitan fatty acid ester include POE(20)-sorbitan trioleate, POE(20)-sorbitan monolaurate, POE(20)-sorbitan monopalmitate, POE(20)-sorbitan monostearate, POE(20)-sorbitan monooleate, and POE(160)-sorbitan triisostearate.

It is preferable that the organic compound further has one or more hydroxyl groups in one molecule, from the viewpoint of easy formation of hydrogen bonding with the low relative permittivity material and further suppression of a polishing speed for a low relative permittivity material.

The number of hydroxyl groups that the organic compound has in one molecule is not particularly limited. However, from the viewpoint of preventing a polishing speed for a low relative permittivity material from being excessively suppressed, the number of hydroxyl groups is preferably 10 or less, more preferably 5 or less, and even more preferably 3 or less.

The hydroxyl group may be a terminal hydroxyl group of the aforementioned polyoxyalkylene group, or may be a hydroxyl group that is bonded to a substituent disposed between a polyoxyalkylene group and a monovalent aliphatic hydrocarbon group containing three or more carbon atoms. Among these forms, the hydroxyl group is preferably a terminal hydroxyl group of a polyoxyalkylene group, from the viewpoint of the easy formation of hydrogen bonding with a low relative permittivity material or easy availability.

The lower limit of the molecular weight of the organic compound is preferably 100 or larger, more preferably 200 or larger, and even more preferably 300 or larger. Furthermore, the upper limit of the molecular weight is preferably 100,000 or less, more preferably 50,000 or less, even more preferably 40,000 or less, and particularly preferably 30,000 or less. When the molecular weight is in such a range, a polishing speed for a low relative permittivity material can be sufficiently suppressed.

A lower limit of the content of the organic compound in the polishing composition is preferably 0.001% by mass or more, more preferably 0.005% by mass or more, and even more preferably 0.01% by mass or more, based on the mass of the polishing composition. Furthermore, an upper limit of the content of the organic compound is preferably 1% by mass or less, more preferably 0.5% by mass or less, and even more preferably 0.1% by mass or less, based on the mass of the polishing composition. When the content is in such a range, the effect of suppressing a polishing speed for a low relative permittivity material can be sufficiently attained.

### [Abrasive Grains]

The polishing composition according to one embodiment of the present invention includes abrasive grains. The abrasive grains included in the polishing composition serve to mechanically polish an object to be polished, and to increase a polishing speed by the polishing composition for an object to be polished other than a low relative permittivity material.

The abrasive grains to be used may be any of inorganic particles, organic particles, and organic-inorganic composite particles. Specific examples of the inorganic particles include, for example, particles formed from metal oxides such as silica, alumina, ceria, and titania; silicon nitride particles, silicon carbide particles, and boron nitride particles. Specific examples of the organic particles include, for example, polymethyl methacrylate (PMMA) particles. These abrasive grains may be used singly or as mixtures of two or more kinds thereof. Also, regarding the abrasive grains, a commercially available product may be used, or a synthesized product may be used.

Among these abrasive grains, silica is preferred, and colloidal silica is particularly preferred.

The abrasive grains may be subjected to surface modification. Since conventional colloidal silica has a zeta potential value close to zero under acidic conditions, silica particles do not electrically repel from each other and are likely to aggregate under acidic conditions. In contrast, abrasive grains that are subjected to surface modification so as to have a relatively large negative value of zeta potential even under acidic conditions, strongly repel from each other and are satisfactorily dispersed even under acidic conditions. As a result, storage stability of the polishing composition can be enhanced. Such surface-modified abrasive grains can be obtained by, for example, mixing a metal such as aluminum, titanium or zirconium, or an oxide of such a metal, with abrasive grains, and thereby doping the metal into the surface of the abrasive grains.

Above all, colloidal silica having an organic acid immobilized thereto is particularly preferred. Immobilization of an organic acid onto the surface of colloidal silica included in a polishing composition can be achieved by, for example, chemically binding a functional group of the organic acid to a surface of colloidal silica. Immobilization of an organic acid onto colloidal silica is not accomplished simply by existing colloidal silica and an organic acid together. If sulfonic acid, which is a kind of organic acid, is to be immobilized to colloidal silica, this can be carried out by, for example, the method described in “Sulfonic acid-functionalized silica through quantitative oxidation of thiol groups”, Chem. Commun., 246-247 (2003). Specifically, a colloidal silica having sulfonic acid immobilized on the surface thereof can be obtained by coupling a silane coupling agent having a thiol group, such as 3-mercaptopropyltrimethoxysilane, to colloidal silica, and then oxidizing the thiol group using hydrogen peroxide. Alternatively, if a carboxylic acid is to be immobilized to colloidal silica, this can be carried out by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, a colloidal silica having a carboxylic acid immobilized on the surface thereof can be obtained by coupling a silane coupling agent containing a photoreactive 2-nitrobenzyl ester to colloidal silica, and then irradiating the colloidal silica with light.

Furthermore, cationic silica produced by adding a basic aluminum salt or a basic zirconium salt, which is disclosed in JP 4-214022 A, can also be used as abrasive grains.

A lower limit of an average primary particle size of the abrasive grains is preferably 5 nm or more, more preferably 7 nm or more, and even more preferably 10 nm or more. Furthermore, an upper limit of an average primary particle size of the abrasive grains is preferably 200 nm or less, more preferably 150 nm or less, and even more preferably 100 nm or less. When the average primary particle size is in such a range, a polishing speed by the polishing composition for an object to be polished other than a low relative permittivity material, can be increased, and the generation of scratches (polishing marks) on the surface of an object to be polished after being polished using the polishing composition can be further suppressed. The average primary particle size of the abrasive grains is calculated, for example, based on a specific surface area of abrasive grains as measured by BET method.

A lower limit of an average secondary particle size of the abrasive grains is preferably 25 nm or more, more preferably 30 nm or more, and even more preferably 35 nm or more. Furthermore, an upper limit of an average secondary particle size of the abrasive grains is preferably 300 nm or less, more preferably 260 nm or less, and even more preferably 220 nm or less. When the average secondary particle size is in such a range, a polishing speed by the polishing composition for an object to be polished other than a low relative permittivity material, can be increased, and the generation of scratches (polishing marks) on the surface of an object to be polished after being polished using the polishing composition can be further suppressed. The secondary particles as used herein refer to particles that are formed when abrasive grains are associated within the polishing composition, and this average secondary particle size of the abrasive grains can be measured by, for example, a dynamic light scattering method.

A lower limit of a content of the abrasive grains in the polishing composition is preferably 0.01% by mass or more, more preferably 0.05% by mass or more, and even more preferably 0.1% by mass or more. Furthermore, an upper limit of a content of the abrasive grains in the polishing composition is preferably 50% by mass or less, more preferably 30% by mass or less, and even more preferably 20% by mass or less. If the content of the abrasive grains in the polishing composition is 0.01% by mass or more, a polishing speed for an object to be polished other than a low relative permittivity material can be increased. Also, if the content of the abrasive grains in the polishing composition is 50% by mass or less, a cost of the polishing composition can be lowered, and the occurrence of dishing on the surface of an object to be polished after being polished using the polishing composition can be further suppressed.

### [Other Components]

The polishing composition according to one embodiment of the present invention may further include another component(s) such as a dispersing medium, a solvent, an oxidizing agent, a reducing agent, a complexing agent, a metal anticorrosive, an antiseptic agent, an antifungal agent, a water-soluble polymer, a surfactant, and an organic solvent for dissolving sparingly soluble organic substances, as necessary. In the following description, the another preferred component(s) will be explained.

### [Dispersing Medium or Solvent]

The polishing composition according to one embodiment of the present invention preferably includes a dispersing medium or solvent for dispersing or dissolving each component. For the dispersing medium or solvent, an organic solvent water and the like may be cited. Among them, it is preferable that the polishing composition includes water. Water that does not contain impurities as far as possible is preferred, from the viewpoint that the impurities may inhibit the action of another component (s). Specifically, pure water obtained by removing impurity ions using an ion exchange resin and then removing foreign materials through a filter, ultrapure water, or distilled water is more preferred.

### [Oxidizing Agent]

Specific examples of an oxidizing agent that can be included in the polishing composition according to one embodiment of the present invention include hydrogen peroxide, peracetic acid, percarbonates, urea peroxide, perchloric acid; and persulfates such as sodium persulfate, potassium persulfate, and ammonium persulfate. These oxidizing agents may be used singly, or two or more kinds thereof may be used in mixture.

Among them, persulfate and hydrogen peroxide are preferred, and particularly preferred is hydrogen peroxide.

A lower limit of a content (concentration) of the oxidizing agent in the polishing composition is preferably 0.01% by mass or more, more preferably 0.05% by mass or more, and even more preferably 0.1% by mass or more. As the content of the oxidizing agent becomes smaller, a material cost for the polishing composition can be lowered, and in addition, there is an advantage that burden for treatment of the polishing composition after use in polishing, that is, burden for waste water treatment, can be reduced. Furthermore, there is also an advantage that excessive oxidation of a surface of an object to be polished caused by the oxidizing agent does not easily occur.

An upper limit of a content (concentration) of the oxidizing agent in the polishing composition is preferably 10% by mass or less, more preferably 5% by mass or less, and even more preferably 3% by mass or less. As the content of the oxidizing agent becomes larger, there is an advantage that a polishing speed can increase at the same time of polishing a metal layer.

### [Complexing Agent]

A complexing agent that can be included in the polishing composition according to one embodiment of the present invention serves to chemically etch a surface of an object to be polished, and to increase a polishing speed by the polishing composition of an object to be polished for a metal layer other than a low relative permittivity material.

Examples of the complexing agent that can be used include an inorganic acid or a salt thereof, an organic acid or a salt thereof, a nitrile compound, an amino acid, and a chelating agent. These complexing agents may be used singly or as mixtures of two or more kinds thereof. Also, regarding the complexing agent, a commercially available product may be used, or a synthesized product may be used.

Specific examples of the inorganic acid include, for example, hydrochloric acid, sulfuric acid, nitric acid, carbonic acid, boric acid, tetrafluoroboric acid, hypophosphorous acid, phosphorous acid, phosphoric acid, and pyrophosphoric acid.

Specific examples of the organic acid include, for example, carboxylic acids, such as monovalent carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, lactic acid, glycolic acid, glyceric acid, benzoic acid, and salicylic acid; polyvalent carboxylic acids such as oxalic acid, malonic acid, succinic acid, glutaric acid, gluconic acid, adipic acid, pimelic acid, maleic acid, phthalic acid, fumaric acid, malic acid, tartaric acid, and citric acid. Furthermore, sulfonic acids such as methanesulfonic acid, ethanesulfonic acid and isethionic acid can also be used.

As the complexing agent, a salt of the aforementioned inorganic acid or organic acid may also be used. In the case of using a salt of weak acid and strong base, a salt of strong acid and weak base, or a salt of weak acid and weak base, a pH buffering effect can be expected. Examples of such a salt include, for example, potassium chloride, sodium sulfate, potassium nitrate, potassium carbonate, potassium tetrafluoroborate, potassium pyrophosphate, potassium oxalate, trisodium citrate, potassium (+)-tartrate, and potassium hexafluorophosphate.

Specific examples of the nitrile compound include, for example, acetonitrile, aminoacetonitrile, propionitrile, butyronitrile, isobutyronitrile, benzonitrile, glutaronitrile, and methoxyacetonitrile.

Specific examples of the amino acid include glycine, α-alanine, β-alanine, N-methylglycine, N,N-dimethylglycine, 2-aminobutyric acid, norvaline, valine, leucine, norleucine, isoleucine, phenylalanine, proline, sarcosine, ornithine, lysine, taurine, serine, threonine, homoserine, tyrosine, bicine, tricine, 3,5-diiodotyrosine, β-(3,4-dihydroxyphenyl)-alanine, thyroxine, 4-hydroxyproline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxylysine, creatine, histidine, 1-methylhistidine, 3-methylhistidine, and tryptophan.

Specific examples of the chelating agent include nitrilotriacetic acid, diethylenetriaminepentaacetic acid, ethylenediaminetetraacetic acid, N,N,N-trimethylenephosphonic acid, ethylenediamine-N,N,N′,N′-tetramethylenesulfonic acid, trans-cyclohexanediaminetetraacetic acid, 1,2-diaminopropanetetraacetic acid, glycol ether diaminetetraacetic acid, ethylenediamine-ortho-hydroxyphenylacetic acid, ethylenediaminedisuccinic acid (SS form), N-(2-carboxylatoethyl)-L-aspartic acid, β-alaninediacetic acid, 2-phosphonobutane-1,2,4-tricarboxylic acid, 1-hydroxyethylidene-1,1-diphosphonic acid, N,N′-bis(2-hydroxybenzyl)ethylenediamine-N,N′-diacetic acid, and 1,2-dihydroxybenzene-4,6-disulfonic acid.

Among these, at least one selected from the group consisting of an inorganic acid or a salt thereof, carboxylic acid or a salt thereof, and a nitrile compound is preferred, and from the viewpoint of stability of a complex structure with a metal compound, an inorganic acid or a salt thereof is more preferred.

A lower limit of a content (concentration) of the complexing agent in the polishing composition is not particularly limited since even a small amount of the complexing agent can exhibit effects. When a metal layer other than of a low relative permittivity material is included, from the viewpoint of increasing a polishing speed for the metal layer, a content is preferably 0.001 g/L or more, more preferably 0.01 g/L or more, and even more preferably 0.1 g/L or more. Furthermore, from the viewpoint of preventing dissolution of metal and enhancing a level difference elimination performance, an upper limit of a content (concentration) of the complexing agent in the polishing composition of the present invention is preferably 20 g/L or less, more preferably 15 g/L or less, and even more preferably 10 g/L or less.

### [Metal Anticorrosive]

The polishing composition according to one embodiment of the present invention may include a metal anticorrosive. The incorporation of a metal anticorrosive to the polishing composition can suppress a metal of a metal layer from being dissolved at the time of simultaneously polishing a metal layer such as a barrier layer. Thereby, deterioration of a surface state such as surface roughness of a polished surface can be suppressed.

The metal anticorrosive that can be used is not particularly limited. The metal anticorrosive is preferably a heterocyclic compound or a surfactant. The number of member atoms of the heterocyclic ring in the heterocyclic compound is not particularly limited. Furthermore, the heterocyclic compound may be a monocyclic compound, or may be a polycyclic compound having a fused ring. The metal anticorrosive may be used singly or as a mixture of two or more kinds thereof. Furthermore, regarding the metal anticorrosive, a commercially available product may be used, or a synthesized product may be used.

Examples of the heterocyclic compound that can be used as the metal anticorrosive include nitrogen-containing heterocyclic compounds such as a pyrrole compound, a pyrazole compound, an imidazole compound, a triazole compound, a tetrazole compound, a pyridine compound, a pyrazine compound, a pyridazine compound, a pyrindine compound, an indolizine compound, an indole compound, an isoindole compound, an indazole compound, a purine compound, a quinolidine compound, a quinoline compound, an isoquinoline compound, a naphthyridine compound, a phthalazine compound, a quinoxaline compound, a quinazoline compound, a cinnoline compound, a bteridine compound, a thiazole compound, an isothiazole compound, an oxazole compound, an isoxazole compound, and a furazan compound.

More specific examples include, as the pyrazole compound, for example, 1H-pyrazole, 4-nitro-3-pyrazolecarboxylic acid, 3,5-pyrazolecarboxylic acid, 3-amino-5-phenylpyrazole, 5-amino-3-phenylpyrazole, 3,4,5-tribromopyrazole, 3-aminopyrazole, 3,5-dimethylpyrazole, 3,5-dimethyl-1-hydroxymethylpyrazole, 3-methylpyrazole, 1-methylpyrazole, 3-amino-5-methylpyrazole, 4-amino-pyrazolo[3,4-d]pyrimidine, allopurinol, 4-chloro-1H-pyrazolo[3,4-D]pyrimidine, 3,4-dihydroxy-6-methylpyrazolo(3,4-B)pyridine, and 6-methyl-1H-pyrazolo[3,4-b]pyridin-3-amine.

Examples of the imidazole compound include imidazole, 1-methylimidazole, 2-methylimidazole, 4-methylimidazole, 1,2-dimethylpyrazole, 2-ethyl-4-methylimidazole, 2-isopropylimidazole, benzimidazole, 5,6-dimethylbenzimidazole, 2-aminobenzimidazole, 2-chlorobenzimidazole, 2-methylbenzimidazole, 2-(1-hydroxyethyl)benzimidazole, 2-hydroxybenzimidazole, 2-phenylbenzimidazole, 2,5-dimethylbenzimidazole, 5-methylbenzimidazole, 5-nitrobenzimidazole, and 1H-purine.

Examples of the triazole compound include 1,2,3-triazole (1H-BTA), 1,2,4-triazole, 1-methyl-1,2,4-triazole, methyl-1H-1,2,4-triazole-3-carboxylate, 1,2,4-triazole-3-carboxylic acid, methyl 1,2,4-triazole-3-carboxylate, 1H-1,2,4-triazole-3-thiol, 3,5-diamino-1H-1,2,4-triazole, 3-amino-1,2,4-triazole-5-thiol, 3-amino-1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazol-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5-dipeptyl-4H-1,2,4-triazole, 5-methyl-1,2,4-triazole-3,4-diamine, 1H-benzotriazole, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5-methyl-1H-benzotriazole, 5,6-dimethyl-1H-benzotriazole, 1-(1′,2′-dicarboxyethyl)benzotriazole, 1-[N,N-bis(hydroxyethyl)aminomethyl]benzotriazole, 1-[N,N-bis(hydroxyethyl)aminomethyl]-5-methylbenzotriazole, and 1-[N,N-bis(hydroxyethyl)aminomethyl]-4-methylbenzotriazole.

Examples of the tetrazole compound include, for example, 1H-tetrazole, 5-methyltetrazole, 5-aminotetrazole, and 5-phenyltetrazole.

Examples of the indazole compound include, for example, 1H-indazole, 5-amino-1H-indazole, 5-nitro-1H-indazole, 5-hydroxy-1H-indazole, 6-amino-1H-indazole, 6-nitro-1H-indazole, 6-hydroxy-1H-indazole, and 3-carboxy-5-methyl-1H-indazole.

Examples of the indole compound include 1H-indole, 1-methyl-1H-indole, 2-methyl-1H-indole, 3-methyl-1H-indole, 4-methyl-1H-indole, 5-methyl-1H-indole, 6-methyl-1H-indole, 7-methyl-1H-indole, 4-amino-1H-indole, 5-amino-1H-indole, 6-amino-1H-indole, 7-amino-1H-indole, 4-hydroxy-1H-indole, 5-hydroxy-1H-indole, 6-hydroxy-1H-indole, 7-hydroxy-1H-indole, 4-methoxy-1H-indole, 5-methoxy-1H-indole, 6-methoxy-1H-indole, 7-methoxy-1H-indole, 4-chloro-1H-indole, 5-chloro-1H-indole, 6-chloro-1H-indole, 7-chloro-1H-indole, 4-carboxy-1H-indole, 5-carboxy-1H-indole, 6-carboxy-1H-indole, 7-carboxy-1H-indole, 4-nitro-1H-indole, 5-nitro-1H-indole, 6-nitro-1H-indole, 7-nitro-1H-indole, 4-nitrile-1H-indole, 5-nitrile-1H-indole, 6-nitrile-1H-indole, 7-nitrile-1H-indole, 2,5-dimethyl-1H-indole, 1,2-dimethyl-1H-indole, 1,3-dimethyl-1H-indole, 2,3-dimethyl-1H-indole, 5-amino-2,3-dimethyl-1H-indole, 7-ethyl-1H-indole, 5-(aminomethyl)indole, 2-methyl-5-amino-1H-indole, 3-hydroxymethyl-1H-indole, 6-isopropyl-1H-indole, and 5-chloro-2-methyl-1H-indole.

Among these, a preferred heterocyclic compound is a triazole compound, and particularly, 1H-benzotriazole, 5-methyl-1H-benzotriazole, 5,6-dimethyl-1H-benzotriazole, 1-[N,N-bis(hydroxyethyl)aminomethyl)-5-methylbenzotriazole, 1-[N,N-bis(hydroxyethyl)aminomethyl]-4-methylbenzotriazole, 1,2,3-triazole, and 1,2,4-triazole are preferred. Since these heterocyclic compounds have high chemical or physical adsorptive power toward a surface of an object to be polished, the heterocyclic compounds can form a stronger protective film on the surface of an object to be polished. This is advantageous for enhancing flatness of the surface of an object to be polished after being polished using the polishing composition of the present invention.

A lower limit of a content of the metal anticorrosive in the polishing composition is preferably 0.001 g/L or more, more preferably 0.005 g/L or more, and even more preferably 0.01 g/L or more, from the viewpoint of preventing dissolution of metal and enhancing level difference elimination performance. Furthermore, from the viewpoint of enhancing a polishing speed of an object to be polished for a metal layer other than a low relative permittivity material, an upper limit of the content of the metal anticorrosive in the polishing composition is preferably 10 g/L or less, more preferably 5 g/L or less, and even more preferably 2 g/L or less.

### [Surfactant]

The polishing composition according to one embodiment of the present invention preferably includes a surfactant. The surfactant is different from the organic compound that is essentially included in the polishing composition according to the present invention.

A surfactant can prevent dishing in polishing a metal wiring by imparting hydrophilicity to a polished surface after polishing. In addition to this, by adsorbing the surfactant to a wafer surface to form a surfactant layer, any damage caused by a chemical included in the polishing composition can be suppressed.

The surfactant may be anyone of an anionic surfactant, a cationic surfactant, an amphoteric surfactant, and a nonionic surfactant.

Specific examples of the anionic surfactant include a fatty acid salt, a polyoxyethylene alkyl ether acetic acid, a polyoxyethylene alkyl sulfuric acid ester, an alkyl sulfuric acid ester, a polyoxyethylene alkyl sulfuric acid, an alkyl sulfuric acid, an alkyl benzenesulfonic acid, an alkyl phosphoric acid ester, a polyoxyethylene alkyl phosphoric acid ester, a polyoxyethylene sulfosuccinic acid, an alkyl sulfosuccinic acid, an alkyl naphthalenesulfonic acid, an alkyl diphenyl ether disulfonic acid, lauric acid, and salts thereof.

Specific examples of the cationic surfactant include an alkyltrimethylammonium salt, an alkyldimethylammonium salt, an alkylbenzyldimethylammonium salt, and an alkylamine salt.

Specific examples of the amphoteric surfactant include an alkylbetaine and an alkylamine oxide. Specific examples of the nonionic surfactant include a polyoxyethylene alkyl ether, a polyoxyalkylene alkyl ether, a sorbitan fatty acid ester, a glycerin fatty acid ester, a polyoxyethylene fatty acid ester, a polyoxyethylene alkylamine, and an alkylalkanol amide. These surfactants may be used singly, or two or more kinds thereof may be used in combination.

Among these, a preferred surfactant is an anionic surfactant, and a more preferred surfactant is a fatty acid salt. An even more preferred surfactant is triethanolamine laurate, a lauric acid ammonium salt, or a lauric acid metal salt. Here, preferred examples of the lauric acid metal salt include potassium laurate.

A lower limit of a content of the surfactant in the polishing composition is preferably 0.0001% by mass or more, and more preferably 0.001% by mass or more, from the viewpoint of suppressing dishing when metal wiring is polished. Furthermore, an upper limit of the content of the surfactant in the polishing composition is preferably 10% by mass or less, and more preferably 1% by mass or less, from the viewpoint of decreasing a residual amount of surfactant on the polished surface, and further improving cleaning efficiency.

### [Antiseptic Agent and Antifungal Agent]

Examples of the antiseptic agent and antifungal agent that can be added to the polishing composition according to the present invention include isothiazoline-based antiseptic agents such as 2-methyl-4-isothiazolin-3-one and 5-chloro-2-methyl-4-isothiazolin-3-one; paraoxybenzoic acid esters; and phenoxyethanol. These antiseptic agents and antifungal agents may be used singly, or may be used as mixtures of two or more kinds thereof.

### [Water-Soluble Polymer]

A water-soluble polymer may be incorporated to the polishing composition according to one embodiment of the present invention, for the purpose of enhancing hydrophilicity of a surface of an object to be polished, or enhancing dispersion stability of the abrasive grains. The water-soluble polymer is different from the organic compound that is essentially included in the polishing composition according to the present invention. Examples of the water-soluble polymer include a polystyrenesulfonic acid salt, a polyisoprenesulfonic acid salt, a polyacrylic acid salt, polymaleic acid, polyitaconic acid, polyvinyl acetate, polyvinyl alcohol, polyglycerin, polyvinylpyrrolidone, a copolymer of isoprenesulfonic acid and acrylic acid, a polyvinylpyrrolidone-polyacrylic acid copolymer, a polyvinylpyrrolidone-vinyl acetate copolymer, a salt of naphthalenesulfonic acid-formalin condensate, a diallylamine hydrochloride-sulfur dioxide copolymer, carboxymethyl cellulose, a salt of carboxymethyl cellulose, hydroxyethyl cellulose, hydroxypropyl cellulose, pullulan, chitosan, and chitosan salts.

In the case of incorporating a water-soluble polymer in the polishing composition, a surface roughness of an object to be polished after being polished using the polishing composition can be further decreased. These water-soluble polymers may be used singly, or two or more kinds thereof may be used in combination.

From the viewpoint that as a content of the water-soluble polymer increases, a surface roughness of a polished surface by the polishing composition is further decreased, a lower limit of a content of the water-soluble polymer in the polishing composition is preferably 0.0001 g/L or more, and more preferably 0.001 g/L or more. From the viewpoint that as the content of the water-soluble polymer decreases, a residual amount of the water-soluble polymer on the polished surface is decreased and thus the cleaning efficiency can be further enhanced, an upper limit of the content of the water-soluble polymer in the polishing composition is preferably 10 g/L or less, and more preferably 5 g/L or less.

### [pH of Polishing Composition]

A lower limit of pH of the polishing composition according to one embodiment of the present invention is preferably 1.5 or higher, more preferably 2 or higher, and even more preferably 2.5 or higher, from the viewpoint of preventing corrosion of a polishing apparatus and corrosion of a wiring and the barrier film.

Furthermore, from the viewpoint of suppressing dissolution of the abrasive grains or the low relative permittivity material, an upper limit of pH of the polishing composition is preferably 12 or lower, more preferably 11.5 or lower, and even more preferably 11 or lower.

A pH adjusting agent may be used for adjusting the pH of the polishing composition to a desired value. The pH adjusting agent to be used may be any of an acid or a base, and may be any one of inorganic and organic compounds. Meanwhile, the pH adjusting agent may be used singly, or two or more kinds thereof may be used as mixtures. When a compound having a pH adjusting function (for example, various acids and the like) is used as the additive as mentioned above, the additive may be utilized as at least a part of the pH adjusting agent.

Examples of the acid that can be used as the pH adjusting agent include inorganic acids such as sulfuric acid, nitric acid, boric acid, carbonic acid, hypophosphorous acid, phosphorous acid, and phosphoric acid; and organic acids including carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and organic sulfuric acids such as methanesulfonic acid, ethanesulfonic acid, and isethionic acid.

Specific examples of the base that can be used as the pH adjusting agent include hydroxides of alkali metals or salts thereof, hydroxides of alkaline earth metals or salts thereof, quaternary ammonium hydroxide or salts thereof, ammonia, and amines. Specific examples of the alkali metals include potassium and sodium. Specific examples of the salts include a carbonate, a hydrogen carbonate, a sulfate, and an acetate. Specific examples of the quaternary ammonium include tetramethylammonium, tetraethylammonium, and tetrabutylammonium.

Quaternary ammonium hydroxide compounds include quaternary ammonium hydroxide or salts thereof, and specific examples thereof include tetramethylammonium hydroxide, tetraethylammonium hydroxide, and tetrabutylammonium hydroxide.

Specific examples of amines include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, piperazine anhydride, piperazine hexahydrate, 1-(2-aminoethyl)piperazine, N-methylpiperazine, and guanidine. These bases may be used singly, or two or more kinds thereof may be used in combination.

Among these bases, ammonia, an ammonium salt, an alkali metal hydroxide, an alkali metal salt, a quaternary ammonium hydroxide compound, and an amine are preferred. More preferably, ammonia, a potassium compound, sodium hydroxide, a quaternary ammonium hydroxide compound, ammonium hydrogen carbonate, ammonium carbonate, sodium hydrogen carbonate, and sodium carbonate are applicable. Furthermore, it is more preferable that the polishing composition includes a potassium compound as a base, from the viewpoint of preventing metal contamination. Examples of the potassium compound include potassium hydroxide or salts thereof, and specific examples include potassium hydroxide, potassium carbonate, potassium hydrogen carbonate, potassium sulfate, potassium acetate, and potassium chloride.

### [Method for Producing Polishing Composition]

The method for producing a polishing composition according to one embodiment of the present invention is not particularly limited, and for example, a polishing composition can be obtained by stirring and mixing abrasive grains, an organic compound, and optionally another component (s) in water.

That is, according to another embodiment of the present invention, there is provided a method for producing a polishing composition used for polishing a material having a relative permittivity of 4 or less, the method including a step of mixing abrasive grains and an organic compound, wherein the organic compound has a polyoxyalkylene group and an aliphatic hydrocarbon group having three or more carbon atoms.

A temperature in mixing each component is not particularly limited. The temperature is preferably 10° C. to 40° C., and the mixing may also be carried out under heated in order to increase a dissolution rate. A mixing time is also not particularly limited.

### [Polishing Method and Method for Producing Substrate]

As explained above, the polishing composition according to one embodiment of the present invention is suitably used for polishing an object to be polished containing a material having a relative permittivity material of 4 or less. The material having a relative permittivity of 4 or less, as an object to be polished for the polishing composition according to one embodiment of the present invention, can form an LSI together with a barrier layer as an interlayer insulating film and a metal wiring layer.

Therefore, according to further another embodiment of the present invention, there is also provided a polishing method for polishing an object to be polished containing a material having a relative permittivity of 4 or less, using the polishing composition of the present invention.

Furthermore, according to still another embodiment of the present invention, there is also provided a method for producing a substrate, the method including a step of polishing an object to be polished containing a material having a relative permittivity of 4 or less by the polishing method described above.

Regarding a polishing apparatus, a general polishing apparatus which is equipped with a holder for retaining a substrate or the like having an object to be polished, and a motor or the like capable of varying the number of rotation, and has a polishing table to which a polishing pad (polishing cloth) can be attached, can be used.

Regarding the polishing pad, a nonwoven fabric, a polyurethane polishing pad, a suede type polishing pad, a porous fluororesin and the like can be used without particular limitations. It is preferable that the polishing pad is subjected to grooving for the retention of polishing liquid.

There are no particular limitations on polishing conditions, and for example, a rotation speed of the polishing table is preferably 10 to 500 rpm, the number of carrier rotations is preferably 10 to 500 rpm, and a pressure applied to a substrate having an object to be polished (polishing pressure) is preferably 0.1 to 10 psi. A method for supplying the polishing composition to the polishing pad is also not particularly limited, and for example, a method of continuously supplying the polishing composition with a pump or the like can be employed. Although a supply amount of the polishing composition is not limited, it is preferably such that a surface of the polishing pad is always covered with the polishing composition of the present invention.

After completion of polishing, the substrate is washed with flowing water, and is dried by dropping the water droplets adhering onto the substrate by means of a spin drier or the like. Thereby, a substrate containing a material having a relative permittivity of 4 or less can be obtained.

The polishing composition according to one embodiment of the present invention may be a one-liquid type composition, or may be a multi-liquid type composition including a two-liquid type composition. Furthermore, the polishing composition according to one embodiment of the present invention may also be prepared by diluting a stock solution of the polishing composition to, for example, 10 or more times using a diluent such as water.

### EXAMPLES

The present invention will be described in more detail using the following Examples and Comparative Examples. However, the technical scope of the present invention is not intended to be limited to the following Examples only.

### Examples 1 to 8 and Comparative Examples 1 to 11

Colloidal silica (average secondary particle size of about 65 nm (average primary particle size: 30 nm, degree of association: 2)) as abrasive grains, triethanolamine-laurate or potassium laurate as a surfactant, and as an organic compound, an organic compound according to the present invention having a polyoxyalkylene group and an aliphatic hydrocarbon group containing three or more carbon atoms, or an organic compound other than that, were mixed under stirring (mixing temperature: about 25° C., mixing time: about 10 minutes) in water so as to give a concentration indicated in the following Table 2 and Table 3, to prepare a polishing composition. A pH of the composition was adjusted to 7 by adding potassium hydroxide (KOH), and the pH was checked using a pH meter. The weight average molecular weight of the organic compound was measured by GPC (gel permeation chromatography) using polystyrene as a standard.

As an object to be polished, a wafer obtained by forming a film of BLACKDIAMOND (registered trademark) (IIx) (relative permittivity k=2.6) on a silicon substrate was used.

For the polishing compositions thus obtained, a polishing speed was measured in polishing a surface of an object to be polished for 60 seconds using the polishing composition under the polishing conditions indicated in the following Table 1. The polishing speed for a low relative permittivity film was determined by dividing a difference between the thicknesses of the film before and after polishing, which were measured using a light interference type film thickness analyzer, by the polishing time.

TABLE 1
Polishing condition 1

Polishing apparatus: Tabletop polishing machine ENGIS
Polishing pad: Suede type polishing pad (hardness 42)
Polishing pressure: 3.0 psi (about 20.9 kPa)
Rotation number of polishing table: 90 rpm
Supply of polishing composition: Constant flow
Supply amount of slurry: 100 ml/min
Rotation number of carrier: 50 rpm

TABLE 2

| | | Potassium | | | | BD(IIx) |
|---|---|---|---|---|---|---|
| | Abrasive | hydroxide | Triethanolamine | Organic compound | | polishing |
| | grains | concentration | laurate | | Concentration | speed |
| | [mass %] | [mass %] | [mass %] | Compound | [mass %] | (Å/min) |
| Example 1 | 0.435 | 0.006 | 0.014 | POE(20)-sorbitan trioleate | 0.05 | 82 |
| | | | | Mw: 428.6 | | |
| Comparative | 0.435 | 0.006 | 0.014 | — | 0 | 137 |
| Example 1 | | | | | | |
| Comparative | 0.435 | 0.006 | 0.014 | Polyacryloylmorpholine | 0.05 | 104 |
| Example 2 | | | | Mw: 51000 | | |
| Comparative | 0.435 | 0.006 | 0.014 | Poly-N-isopropyl acrylamide | 0.05 | 141 |
| Example 3 | | | | Mw: 60000 | | |
| Comparative | 0.435 | 0.006 | 0.014 | Polyvinyl alcohol | 0.05 | 126 |
| Example 4 | | | | Mw: 21000 | | |
| Comparative | 0.435 | 0.006 | 0.014 | Polyvinyl alcohol | 0.05 | 126 |
| Example 5 | | | | Mw: 114000 | | |
| Comparative | 0.435 | 0.006 | 0.014 | Polyvinyl alcohol | 0.05 | 311 |
| Example 6 | | | | Mw: 19000 | | |
| Comparative | 0.435 | 0.006 | 0.014 | Polyacrylic acid-silicone graft | 0.05 | 180 |
| Example 7 | | | | polymer | | |
| Comparative | 0.435 | 0.006 | 0.014 | Polyvinylpyrrolidone | 0.05 | 132 |
| Example 8 | | | | Mw: 50000 | | |
| Comparative | 0.435 | 0.006 | 0.014 | Polyvinyl alcohol-polyvinyl | 0.05 | 152 |
| Example 9 | | | | pyrrolidone graft copolymer | | |
| | | | | Mw: 85000 | | |
| Comparative | 0.435 | 0.006 | 0.014 | Polyvinyl alcohol-polyvinyl | 0.05 | 129 |
| Example 10 | | | | pyrrolidone graft copolymer | | |
| | | | | Mw: 43000 | | |

TABLE 3

| | | Potassium | | | | BD(IIx) |
|---|---|---|---|---|---|---|
| | Abrasive | hydroxide | Potassium | Organic compound | | polishing |
| | grains | concentration | laurate | | Concentration | speed |
| | [mass %] | [mass %] | [mass %] | Compound | [mass %] | (Å/min) |
| Example 2 | 0.435 | 0.006 | 0.003 | POE(20)-sorbitan trioleate | 0.05 | 3 |
| | | | | Mw: 428.6 | | |
| Example 3 | 0.435 | 0.006 | 0.003 | POE(20)-sorbitan monolaurate | 0.05 | 6 |
| | | | | Mw: 1227.5 | | |
| Example 4 | 0.435 | 0.006 | 0.003 | POE(20)-sorbitan monopalmitate | 0.05 | 10 |
| | | | | Mw: 1283 | | |
| Example 5 | 0.435 | 0.006 | 0.003 | POE(20)-sorbitan monostearate | 0.05 | 9 |
| | | | | Mw: 1311.7 | | |
| Example 6 | 0.435 | 0.006 | 0.003 | POE(20)-sorbitan monooleate | 0.05 | 7 |
| | | | | Mw: 604.8 | | |
| Example 7 | 0.435 | 0.006 | 0.003 | POE(160)-sorbitan triisostearate | 0.05 | 3 |
| | | | | Mw: 8005.8 | | |
| Example 8 | 0.435 | 0.006 | 0.003 | POE(5)-1-hexyl heptyl ether | 0.05 | 20 |
| | | | | Mw: 451.5 | | |
| Comparative | 0.435 | 0.006 | 0.003 | None | 0 | 47 |
| Example 11 | | | | | | |

As shown in Table 2, it is noted that the polishing composition of the present invention (Example 1) can suppress a polishing speed for a BLACKDIAMOND (registered trademark) film as a low relative permittivity material, as compared to the polishing compositions of Comparative Examples 1 to 10 containing no organic compound according to the present invention.

Further, as shown in Table 3, it is noted that the polishing compositions of the present invention (Examples 2 to 8) can suppress a polishing speed for a BLACKDIAMOND (registered trademark) film as a low relative permittivity material, as compared to the polishing composition of Comparative Example 11, containing no organic compound according to the present invention.

Furthermore, as shown in Table 3, it is noted that the polishing compositions containing a sorbitan derivative as the organic compound (Examples 2 to 7) have an improved effect of suppressing a polishing speed, as compared to the polishing composition containing no sorbitan derivative (Example 8).

The present application is based on Japanese Patent Application No. 2014-176271 filed on Aug. 29, 2014, the entire disclosure of which is incorporated by reference.

1.-9. (canceled)

10. A polishing composition used for polishing a material having a relative permittivity of 4 or less, the polishing composition comprising:
abrasive grains; and
an organic compound,
wherein the organic compound has a polyoxyalkylene group and an aliphatic hydrocarbon group containing three or more carbon atoms.

11. The polishing composition according to claim 10, wherein an average number of added moles of the polyoxyalkylene group is 2 or larger.

12. The polishing composition according to claim 10, wherein the polyoxyalkylene group is a polyoxyethylene group.

13. The polishing composition according to claim 10, wherein the polyoxyalkylene group is a polyoxyethylene group having an average number of added moles of 5 or larger.

14. The polishing composition according to claim 10, wherein the organic compound further has one or more hydroxyl groups in one molecule.

15. The polishing composition according to claim 10, wherein the organic compound is a sorbitan derivative.

16. A method for producing a polishing composition used for polishing a material having a relative permittivity of 4 or less, the method comprising:
a step of mixing abrasive grains and an organic compound,
wherein the organic compound has a polyoxyalkylene group and an aliphatic hydrocarbon group having three or more carbon atoms.

17. A polishing method which comprises polishing an object to be polished containing a material having a relative permittivity of 4 or less using the polishing composition set forth in claim 10.

18. A method for producing a substrate, the method comprising a step of polishing an object to be polished containing a material having a relative permittivity of 4 or less by the polishing method set forth in claim 17.
